(19) United States
(12) Patent Application Publication
(10) Pub. No.: US 2019/0140617 A1
(43) Pub. Date: May 9, 2019

(54) SAW FILTER WITH INTERFERENCE MODE SUPPRESSION

(71) Applicant: SNAPTRACK, INC., San Diego, CA (US)

(72) Inventor: Quirin UNTERREITHMEIER, Munich (DE)

(21) Appl. No.: 16/096,543

(22) PCT Filed: May 30, 2017
(86) PCT No.: PCT/US2017/034977

§ 371 Date: Oct. 25, 2018

(30) Foreign Application Priority Data
Jun. 1, 2016 (DE) 102016110139.7

(51) Int. Cl. H03H 9/145; H03H 9/02

(52) U.S. Cl. CPC H03H 9/14547; H03H 9/1457; H03H 9/02834; H03H 9/02559

(57) ABSTRACT

In a first group (FG1) of transducer fingers of an interdigital transducer of the SAW filter, a geometric parameter (eta) determining the resonance of the main mode of the transducer is varied in the transverse direction (TR) with a first increment. In a second group (FG2) of transducer fingers (EF), the geometric parameter is varied with a second increment that is opposed in effect to the first, so that the transverse geometric variation of the first and the second groups of transducer fingers accordingly compensate for each other, wherein the resonance of the main mode (M1) remains unchanged, while the interfering secondary mode (M2) is suppressed.

### CROSS-REFERENCE TO RELATED APPLICATIONS

The present Application for Patent claims priority to German Patent Application No. 102016110139.7, filed Jun. 1, 2016, which is hereby expressly incorporated by reference herein in its entirety.

### DESCRIPTION

In order to reduce the temperature response of SAW filters, they are provided with a compensation layer, usually including SiO₂. A side effect of this measure, however, is that the coupling is reduced. Broadband filters having such compensation layers can therefore be produced only on highly coupled substrates such as lithium niobate LN.

Bandpass filters made of SAW resonators having a compensation layer can, for example, be made on lithium niobate crystals having a red-128 cut angle. The resonance frequency of the acoustic Rayleigh mode is used on this substrate material.

Many filters having specific material combinations for electrodes and the layers deposited thereupon, and/or for specific layer thickness combinations are capable of propagating parasitic modes, in particular a disk mode. The resonance frequency of the disk mode is above the resonance frequency of the Rayleigh mode. For the serial resonators of a filter, the resonances of the disk mode are above the passband of the filter and cause sharp drops in the transmission function of the filter. Even if the geometry of this filter is optimized for maximum suppression of the interference mode, it can be enhanced as a result of geometric deviations caused by tolerances and under temperature and power loads. This can cause an increased temperature and power load on the resonators that could result in premature wear and, ultimately, failures of the filter. In other cases, the frequency of an interference mode is at another usage frequency that is also shared by the device having the filter arrangement and operation at this frequency is disturbed.

In the case of other material combinations, other interference modes can also occur that unacceptably interfere with the filter characteristics in the range of the passband or in other important frequency ranges.

An extensive suppression of the interfering SH mode is successful if the electrical coupling of this mode is reduced. This can be achieved by a carefully optimized geometry in which the layer heights of dielectric layers as well as the width and the height of the transducer fingers are controlled within narrow limits. This sets narrow tolerances for the manufacturing process, however.

The object of the present invention is thus to reliably and continuously suppress interference modes and, in particular, interference modes of a SAW filter.

This object is achieved by a SAW filter according to claim 1. Advantageous embodiments of the invention are provided in additional claims.

The proposed SAW filter has an interdigital transducer whose transducer fingers are arranged in succession in the longitudinal direction in relation to their finger centers in a first periodicity. The periodicity determines the resonance frequency of the transducer, which corresponds to the resonance of the main mode. Hereinafter, the resonance of the transducer is always understood to include the resonance of the main mode unless another resonance is specifically indicated.

The transducer fingers of the transducer form a first and a second group or are assigned to either a first or a second group of transducer fingers. In the first group, a first increment changes a geometric parameter that determines the resonance in the transverse direction. In the second group of transducer fingers, a second increment changes a geometric parameter that determines the resonance in the transverse direction and is opposed to the first increment or produces an effect opposed to the first increment.

In the present case, the variation of the geometric parameter in the transducer fingers of the second group, when considered by itself in isolation, causes a frequency change which is opposed to the one caused by the corresponding variation in the transducer fingers of the first group.

The transverse variations in the first and second groups of transducer fingers thus compensate for each other with respect to their effects on the resonance of the main mode. Thus, a consistent resonance of the main mode is present in any transverse subsection of the transducer.

At the same time, the resonance frequency of an interfering secondary mode is affected by the transverse variation of the geometric parameters. In contrast to the corresponding effect on the main mode, however, the effects of the transverse changes in the first and second groups of transducer fingers do not compensate for each other with respect to the secondary mode. This results in a variation of the secondary mode resonance frequency in the transverse direction, whereby the interfering resonance peak spreads in the spectrum. The excitation of the secondary mode is thus reduced overall and the secondary mode is suppressed.

For virtually all interdigital transducers, a geometric parameter can be found that, when changed, can affect the resonance frequency of the transducer's main mode. Typically, such a geometric change shifts also the resonance frequency of the secondary mode. In most cases, the dependency of the resonance frequencies on the change of the geometric parameters is different for the two modes. This means that the resonance frequencies of the main and secondary modes can be shifted to varying degrees by a given geometric parameter change.

For each change of the geometric parameters or for each shift of the resonance frequency caused by the change of the geometric parameter in a group of transducer fingers, there is at least one geometric setting in the second group of transducer fingers that precisely compensates for this shift in the main mode. Because of the different dependencies with which the resonance frequency of the main mode and the secondary mode react to a change in the geometric parameters, compensation cannot be achieved for the secondary mode. As a result, the resonance of the secondary mode shifts and varies over the transverse direction in transverse subsections. This results in a lower excitation of the secondary mode, to a reduced or damped noise signal through the secondary mode in the case of an unmodified main mode.

In an advantageous embodiment of the invention, the number of transducer fingers is equal in both groups. This means that a transducer finger of a first group can be assigned to exactly one transducer finger of a second group. Preferably the transducer fingers of the two groups are arranged alternately in the longitudinal direction. By using the alternating arrangement, a higher homogeneity is achieved in the transducer and the transmission properties are influenced positively.

The geometric parameter, whose change affects the resonance frequency of the transducer, can be chosen from among: finger width, mass allocation of the transducer fingers and metalization thickness η. For the metalization thickness η, it is important that it is not only dependent upon the fingers of the finger group and, therefore, also cannot be set independently of the electrode fingers of the second finger group.

If the finger width of a first group of transducer fingers is increased in the transverse direction, then it must usually be decreased in the second group of transducer fingers in the transverse direction. The change in the geometric parameter of the second group must usually take place with a different amount, thus having the consequence that in the transverse direction not only the finger width of the transducer fingers of the two finger groups changes, but also the metalization thickness η.

It is generally not possible to fully compensate for the effects of geometric parameter changes in the first and the second finger groups by mutually symmetrical geometric parameter changes.

In the case of constant periodicity of the transducer fingers, the finger width cannot be changed independently of the finger spacing or of the spacing of the finger centers. A change of the finger spacing alone when the remaining parameters remain otherwise constant would result in a change in the periodicity. This is only permissible, however, if the change in periodicity for fingers of the first group has an effect on the resonance frequency that can be equalized again by a corresponding change in the second group.

In an advantageous embodiment, the transverse variation of the geometric parameter takes place continuously, for example, and conforms to a continuous function. Continuous changes are possible that follow a linear or a non-linear function.

It is also possible to change the geometric parameter in the transverse direction stepwise, so that the geometric parameter in a transverse section of the transducer is constant, whereas the adjacent one varies stepwise. Such a stepped geometric change includes at least two adjacent transverse sections. Even with just two sections, the effect according to the invention of suppressing the secondary mode is achieved if the geometric changes in the two transverse sections have different effects on the resonance of the main and secondary modes.

However, the transducer can be divided into any number of transverse sections, so that an infinite, yet continuous change can be achieved.

A SAW filter according to the invention may have a layer stack with a piezoelectric substrate overlain by a metalization layer in which the transducer fingers are formed and, over that, a dielectric layer or a dielectric layer sequence. In one embodiment of the invention, materials and/or layer thicknesses of the layer stack can now be varied in such a way that the extent of mode influence on the main mode and the secondary mode is maximally different. In this manner, a maximum suppression of the interfering secondary mode can be achieved by corresponding geometric variations.

In the aforementioned layer stack, the desired effect for changing the geometric parameter of the transducer fingers can also be increased by a regularly structured layer, which is arranged over or under the transducer fingers and is applied over the dielectric layer, for example.

The structured layer can have a periodicity in the longitudinal direction that corresponds to the periodicity of the metalization layer or of the transducer fingers.

Additionally or alternately, the structured layer can have a transverse variation of a geometric parameter.

It is also possible to double the periodicity of the structures in the structured layer, which, by alternately arranging the transducer fingers of the first and second groups, results in the periodicity of the structured layer corresponding to the periodicity of a group of transducer fingers, and this, therefore, affects only this group of transducer fingers.

In the case of a different sequence of transducer fingers of the first and second finger groups, a different periodicity corresponding to the respective finger group can also be set in the structured layer.

Transducer fingers of this group and the structured layer can then interact in such a way that the two transverse geometric variations together influence the resonance frequency of the transducer.

The invention will be explained in greater detail below with reference to exemplary embodiments and the accompanying figures. The figures are, in part, only shown schematically and only serve for better understanding and are, therefore, not to scale. Individual parts can be depicted enlarged, reduced, simplified or distorted.

### BRIEF DESCRIPTION OF THE DRAWINGS

FIG. 1 shows the transmission behavior of a filter having an interference mode,

FIG. 2 shows the frequency dependence of two propagation-capable modes of one geometric parameter,

FIG. 3 shows a frequency distribution of two modes capable of propagation in the transverse direction across the aperture of a transducer according to the invention,

FIG. 4 shows a variation of finger widths of transducer fingers of the first and second groups according to the invention,

FIG. 5 shows the relative frequency change of an interference mode across the aperture in the case of a finger width variation according to FIG. 4,

FIGS. 6A to 6G show detailed views of transducer structures,

FIG. 7 shows a cross-section through a SAW Filter in HQTCF technology,

FIG. 8 shows a cross-section through a SAW filter on lithium tantalate,

FIG. 9 shows a cross-section through a SAW Filter having an additional structural layer, and

FIG. 10 shows a variation of an embodiment according to FIG. 9.

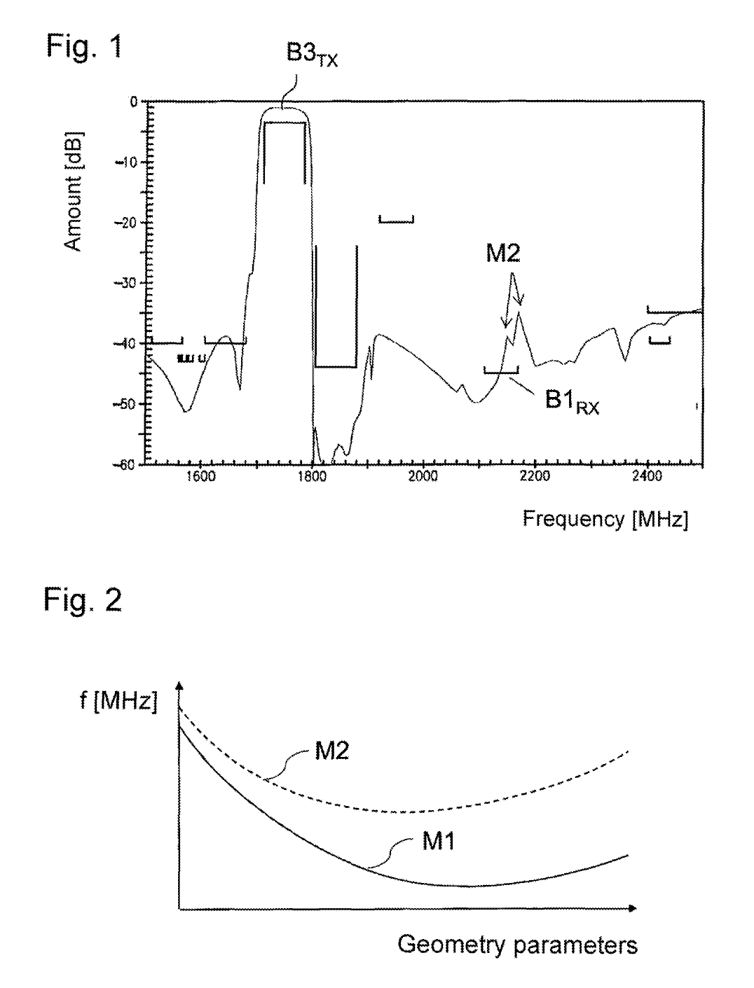

FIG. 1 shows as an arbitrarily chosen example the transfer curve of an HF filter, in this case a TX filter for band 3. The filter is designed with HQTCF technology (High Quality with compensated TCF), which means that a dielectric layer, in particular a SiO₂ layer, is arranged over the transducer structures to compensate for the temperature coefficient of the frequency (TCF). Without additional measures, an interference mode (M2) can occur in such a filter, in this case a disk mode in which the frequency is in particular dependent upon the layer thickness ratios of the HQTCF design. The interference mode results in a peak in the transmission function, which partially overlaps with the frequency range of a different band, in this case the RX band of band 1. If a mobile communications terminal uses band 3 and band 1, reception problems could occur on band 1 because of the interfering disk mode problems.

The basic idea of the invention is to allow the frequency of an interference mode—the origin of which is not directly relevant to the invention—to vary by changing one or a plurality of geometric parameters across the width of the transducer, meaning in the transverse direction, wherein the frequency conditions or the resonance conditions for the main mode are kept constant across the entire aperture.

In a first step, the main and secondary mode dependencies are determined by this geometric parameter.

FIG. 2 shows an imagined exemplary frequency dependency of two modes of one geometric parameter. In the example, the mode according to the curve M1 reacts differently to variations of the geometric parameter than the mode corresponding to the curve M2.

In the next step, a transverse frequency variation caused by a change in the geometric parameters is again compensated by geometric measures. In accordance with the invention, this succeeds if the transducer fingers EF of the interdigital transducer are divided into two groups that are preferably alternately arranged in succession in the longitudinal direction LR. While a variation of the geometric parameter in transducer fingers in the first finger group FG1 results in a frequency shift according to curve M1 from FIG. 2, transducer fingers EF of the second finger group FG2 are varied in one or a plurality of further geometric parameters in such a manner that the frequency shift is compensated by changing the geometric parameters of the first finger group for the main mode M1.

The invention makes it possible to hold the frequency of main mode M1 constant by appropriate geometric variations in first and second finger groups FG1, FG2. Because the frequency of the secondary mode M2 is otherwise a function of the variation in the geometric parameter, the frequency deviation of the secondary mode is not compensated by the geometric parameter variations implemented through first and second finger groups FG1, FG2.

FIG. 3 shows the possible frequency dependency of main and secondary modes of a transducer according to the invention from the transverse standpoint, that is, seen in the transverse direction across the aperture of the transducer. If a transducer according to the invention demonstrates this type of behavior, the resonance peak of the secondary mode becomes wider and is then less interfering. In addition, the coupling of this mode is reduced, resulting in further improvement through additional suppression of the interference mode. The broadening of the resonance of the interference mode and an improved damping through lower coupling result in better filter behavior of the SAW filter, so that the usage bands adjacent to the secondary mode that are within this frequency range are no longer disturbed.

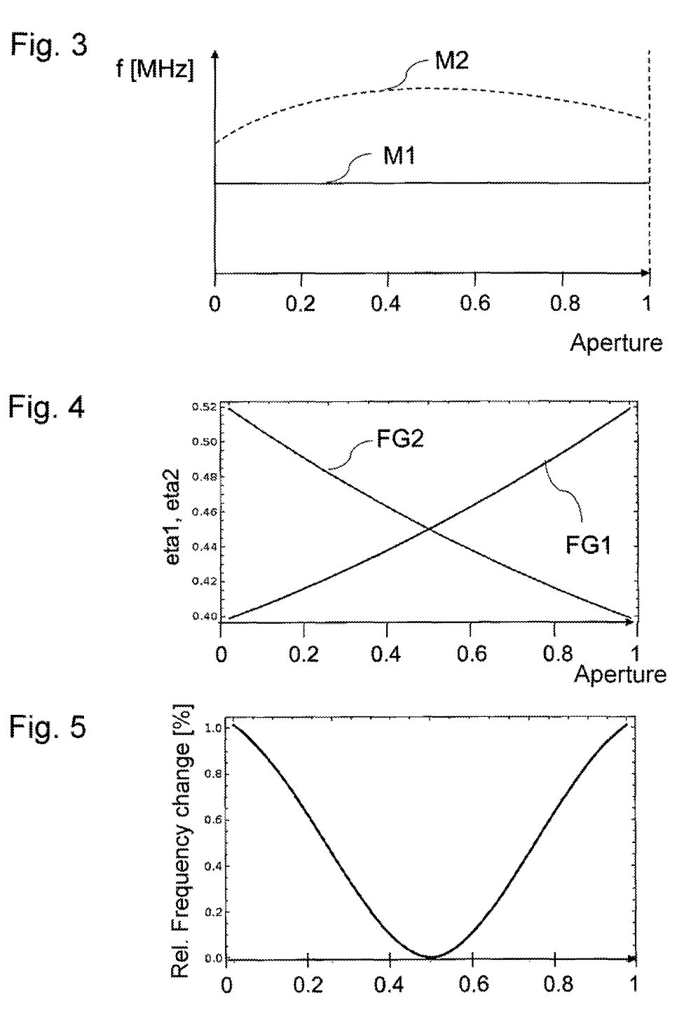

FIG. 4 shows how the finger widths in a transducer according to the invention can be changed across the aperture as a concrete geometric parameter. The finger width is specified in the figure as a metalization thickness (eta), wherein eta is derived from the ratio of the actual finger width to the finger period (here kept constant). Eta therefore behaves in a manner proportional to the finger width. The transducer fingers of the first group have an increasing eta as seen across the aperture, while eta for the transducer fingers of the second group decreases. With such finger width variations in the first and second groups, the resonance frequencies of the main mode can be kept constant across the aperture.

FIG. 5 shows how, in contrast to the main mode, the resonance of the interfering secondary mode varies across the aperture. The relative frequency change of the interference mode, which can be maintained using a finger-width variation according to FIG. 4, is shown here.

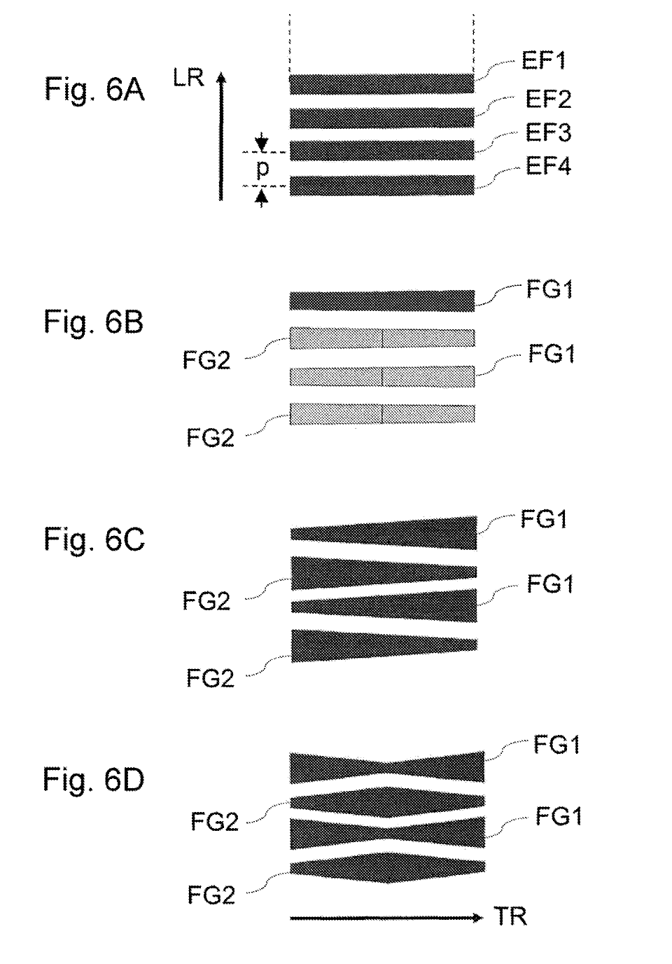

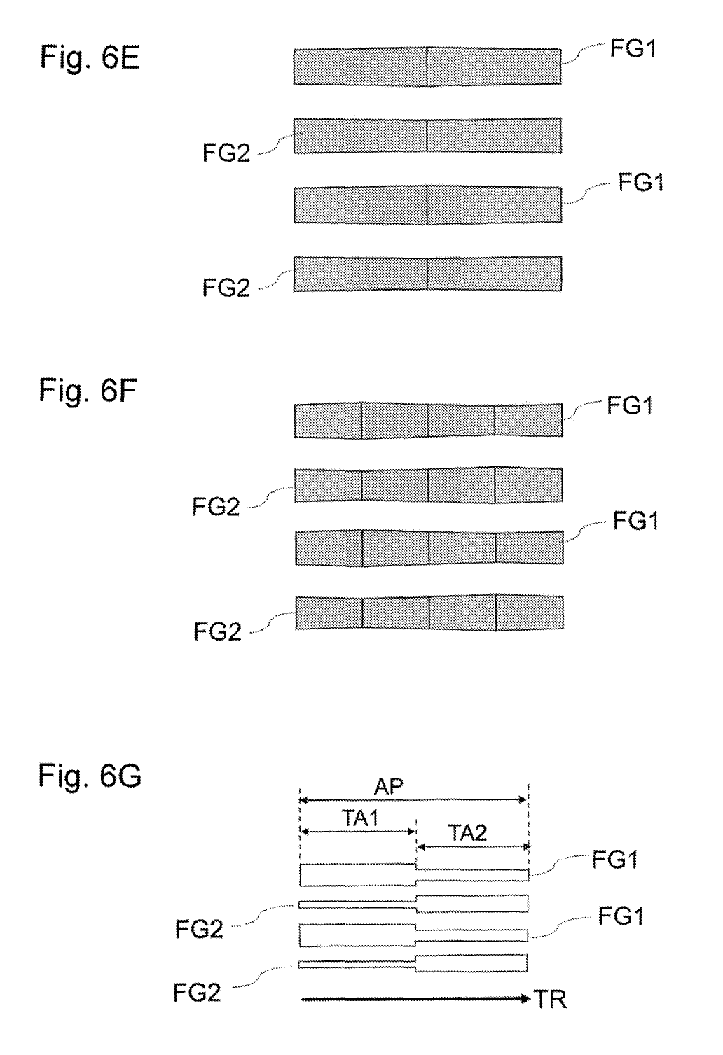

FIGS. 6A to 6B show different metalizations of an interdigital transducer, wherein the transducer in the figures is depicted only in detail sections in reference to four transducer fingers EF.

FIG. 6A shows four transducer fingers EF1 to EF4, which are arranged in succession in longitudinal direction LR. The longitudinal direction corresponds to the propagation direction of the surface wave. Transducer fingers EF are arranged equidistant from each other and preferably alternately connected to different potentials. The spacing of two transducer fingers EF in the center of the transducer corresponds to the finger period p, also called periodicity. Although no geometric variations are evident from the illustration in FIG. 6A, they can be implemented visibly in the transverse direction or by material changes. It is possible, for example, to increase the mass loading in the transverse direction, either by varying the layer thickness of the metalization, by varying the layer thickness of an overlying layer or by applying an additional structure in an additional layer plane.

FIG. 6B shows how the metalization of the transducer fingers is achieved for the exemplary embodiment according to FIG. 4. The finger width of the transducer fingers of the first finger group increases continuously as seen across the aperture, while the finger width for the transducer fingers of the second group decreases.

FIG. 6C again shows this exemplary embodiment in an exaggerated schematic representation. In the illustrated embodiment, the metalization thickness of the whole transducer, meaning the measured metalization thickness across the transducer fingers of the first and the second groups, remains constant because the finger-width variations for fingers of the first and second finger groups precisely compensate for each other. Because the goal is not a compensation of the geometric parameter, but instead a compensation of the frequency shift caused by it, an actual transducer-finger structure having transverse geometric parameter variation differs from that shown in FIG. 6C. For example, while the finger width in first finger group FG1 increases in a linear function across the aperture of the transducer from left to right, a non-linear change in finger widths of the transducer fingers of second group FG2 will be required to compensate for the frequency shift across the aperture effected thereby.

FIG. 6D shows a further principal embodiment of the invention, wherein the variation of the geometric parameter is not across the entire transducer width or across the whole aperture in the same direction. The finger width of the transducer fingers here is again selected as the geometric parameter that first decreases in first finger group FG1 and increases again in the center of the aperture so that an almost mirror plane is produced in the center of the transducer. In a corresponding manner, the finger width of the transducer fingers of second finger group FG2 increases towards the transducer center, wherein the corresponding dimensioning of the finger center in the second finger group is precisely designed to compensate for the frequency shift for main mode M1.

FIG. 6E basically shows the same embodiment, wherein the geometric variation is shown—but not in an exaggerated manner, as in 6D, but in an actual embodiment.

FIG. 6F shows a similar embodiment, wherein the geometric variation of 6E is repeated, but in the transverse direction, so that a periodic geometric change results.

The embodiments according to FIGS. 6E and 6F have the additional advantage that they are symmetrical at the edge because the transducer fingers of both groups are equally wide on both edges.

FIG. 6G shows a detail section of the transducer structure of an interdigital transducer as a further exemplary embodiment, wherein the geometric variation of transducer fingers EF is executed in steps. The exemplary embodiment according to FIG. 6G subdivides the aperture into two transverse subsections TA1, TA2, wherein inside each subsection TA the geometric parameter of at least one finger group can be kept constant. Because precisely one finger width is required for the transducer fingers of the second finger group to compensate the resulting frequency shift, the finger width or some other corresponding geometric parameter can also be held constant in this subsection for the second finger group, but at a different value. This embodiment also succeeds in keeping constant the frequency mode that is a function of the transducer structure in the longitudinal direction across the two subsections, but not the frequency of the secondary mode, which experiences a frequency shift due to the different geometry of the transducer fingers in second transverse subsection TA2. This also results in a broadening of the interference mode peak in the transmission function, so that the filter in the area of the secondary mode has an improved suppression, which allows the use of an additional usage frequency of a different band at this point.

Insofar as a division of the interdigital transducer into two transverse subsections TA does not sufficiently damp the secondary mode or does not sufficiently “smear” its resonance, the transducer must be divided into a higher number of subsections, each having different geometric parameters.

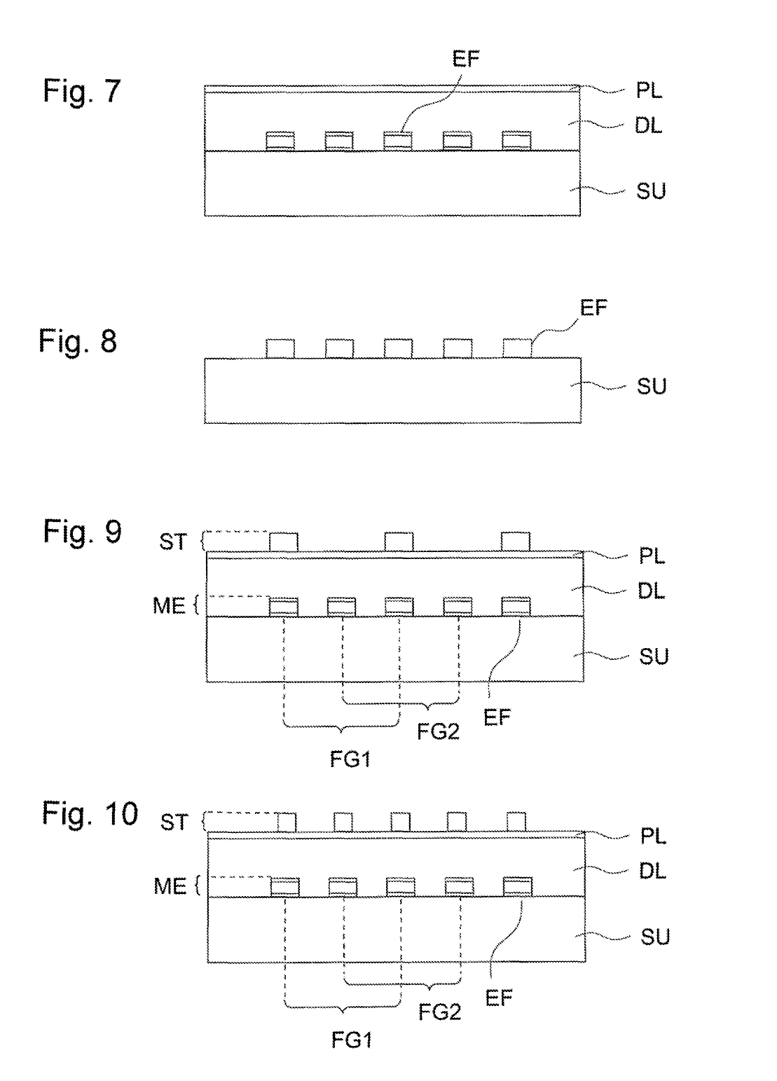

FIG. 7 shows a schematic cross-section through a SAW filter in HQTCF technology. The transducer structures in the form of transducer fingers EF are arranged on a highly coupled piezoelectric substrate SU, on lithium niobate, for example. Transducer fingers EF include at least partial layers of a material heavier than aluminum, such as copper-containing partial layers, or are completely made of a heavier metal. Arranged over transducer fingers EF is a dielectric layer, whose layer thickness is chosen so that the temperature coefficient of the frequency, which is essentially dependent upon the selected substrate material, is compensated. This is achieved for example, by a dielectric layer of SiO₂, which has an influence on the temperature coefficient TCF, which is opposed to that of the substrate and can thus compensate for it. An additional passivation layer PL or any other layers can be arranged over dielectric layer DL.

FIG. 8 shows a SAW filter in a schematic cross-section, wherein transducer fingers EF are manufactured from an aluminum-containing metalization and are applied to any substrate SU, in particular a lithium tantalate substrate.

FIG. 9 shows an embodiment, wherein the frequency shift in the transverse direction that is accomplished using the corresponding geometric parameter variation in the transverse direction can be further strengthened or weakened by a structured layer ST. Such a structured layer can, for example, be applied over dielectric layer DL or over passivation layer PL. It is also possible to provide structured layer ST at a different location in the SAW filter above or below the transducer fingers. Structured layer ST can include a dielectric material or else a metallic material, in particular.

In the embodiment according to FIG. 9, structured layer ST is structured in a striated manner similar to that of the transducer fingers, wherein the striations in this case are arranged only over the transducer fingers of the first finger group. The structured layer can vary in the transverse direction that is vertical to the drawing plane in the figure. The variation can be done similarly to the variation of the geometric parameter of the transducer fingers, but can also be significantly different from it.

FIG. 10 shows a variation of an embodiment according to FIG. 9. In this case, although structured layer ST is also structured in a striated manner, the striations are arranged over transducer fingers EF of first finger group FG1 as well as over the transducer fingers of second finger group FG2. The striations can also deviate in their dimensions from the dimensions of transducer fingers EF underlying each, for example from the striation width or height. The dimensions of the individual striations can also be different even within the structured layer.

The invention could be explained in reference to just a few exemplary embodiments and is, therefore, not limited to these. All possible geometric parameters, which have an influence on the resonance of a mode can be changed, wherein the variations can also be carried out in forms other than those depicted. Because the geometric variations are applied depending upon the mode, different interfering secondary modes can be compensated in this manner. Each variation is then oriented or optimized to precisely one interference mode.

### LIST OF REFERENCE SIGNS

DL dielectric layer

EF converter finger

f Frequency

FG1 first group of transducer fingers

FG2 second group of transducer fingers

LR longitudinal direction

M1 main mode

M2 secondary mode

ME metalization layer

p periodicity of the transducer fingers

ST regularly structured layer

SU piezoelectric substrate

TA transverse section

TR transverse direction

η metalization thickness

1. SAW filter
equipped with an interdigital transducer,
wherein transducer fingers (EF) are arranged in succession in the longitudinal direction (LR) in relation the finger center in a first periodicity,
wherein a geometric parameter (eta) that determines the resonance of the transducer in a first group (FG1) of transducer fingers varies in the transverse direction (TR) with a first increment,
wherein the geometric parameter that determines the resonance of the transducer in a second group (FG2) of transducer fingers (EF) varies in the transverse direction (TR) with a second increment that is opposed to the first increment,
wherein the transverse geometric variations of the first and the second groups of transducer fingers compensate for each other in such a manner that the resonance of the main mode (M1) in the transverse direction remains unchanged in each transverse section (TA),
wherein the resonance of an interfering secondary mode (M2) in the transverse direction varies across the transducer.

2. SAW filter according to the preceding claim, wherein the number of transducer fingers (EF) is equal in both groups (FG1, FG2).

3. SAW filter according to any of the preceding claims, wherein the transducer fingers (EF) of the two groups (FG) are arranged alternately

4. SAW filter according to any of the preceding claims, wherein the geometric parameter is selected from among:
finger width, mass assignment and metalization thickness.

5. SAW filter according to any of the preceding claims, wherein the finger width of the transducer fingers (EF) of the first group (FG1) decreases in the transverse direction (TR), at least over a transverse section (TA), the finger width of the transducer fingers (EF) of the second group (FG2), by contrast, increases in the same transverse direction (TR) over the same transverse section.

6. SAW filter according to any of the preceding claims, wherein the transverse variation of the geometric parameter (eta) follows a continuous linear function.

7. SAW filter according to any of the preceding claims, wherein the geometric parameter (eta) in the transverse direction (TR) varies stepwise from one transverse section (TA1,TA2) to the next.

8. SAW filter according to any of the preceding claims, having a layer stack that includes at least one piezoelectric substrate (SU), a metalization layer (ME) having the transducer fingers and a dielectric layer (DL),
wherein materials and/or layer thicknesses of the layer stack are chosen so that the interfering secondary mode (M2) is maximally suppressed via the transverse geometric variation.

9. SAW filter according to the preceding claim,
wherein a regularly structured layer (ST) is applied over the dielectric layer (DL) that has the same periodicity (p) as the first group (FG1) of transducer fingers (EF),
wherein the structured layer has a transverse variation of a geometric parameter (eta),
wherein the structured layer (ST) and the transducer fingers (EF) of the first group (FG1) interact accordingly and in so doing influence the resonance frequency of an interference mode of the transducer.
